(19) United States
(12) Patent Application Publication
(10) Pub. No.: US 2026/0155182 A1
(43) Pub. Date: Jun. 4, 2026

(54) Program Operations in Memory Devices

(71) Applicant: Yangtze Memory Technologies Co., Ltd., Wuhan (CN)

(72) Inventors: Li XIANG, Wuhan (CN); Ruxin WEI, Wuhan (CN); Jinchi HAN, Wuhan (CN)

(21) Appl. No.: 19/019,759

(22) Filed: Jan. 14, 2025

(30) Foreign Application Priority Data
Nov. 29, 2024 (CN) 202411750389.1

(51) Int. Cl. G11C 16/10; G11C 16/04; G11C 16/08

(52) U.S. Cl. CPC G11C 16/10; G11C 16/0483; G11C 16/08

(57) ABSTRACT

Example memory devices, systems, and methods for improving program operation of a memory cell in the memory cell array are disclosed. One example method includes a program operation a prepare phase, a boosting phase, a program phase, and a recovery phase. During the boosting phase, a first boost voltage is applied to a first word line coupled to the first memory cell and a second boost voltage is applied to second word lines adjacent to the first word line. The program phase includes a first and a second pulse phase. During the first pulse phase, a first pulse voltage is applied to the first word line, and a second pulse voltage is applied to the second word lines. The first word line is floated during the second pulse phase, where a voltage of the first word line is increased from the first pulse voltage to a fourth pulse voltage.

### CROSS-REFERENCE TO RELATED APPLICATIONS

This application claims priority to Chinese Patent Application No. 202411750389.1, filed on Nov. 29, 2024, which is hereby incorporated by reference in its entirety.

### TECHNICAL FIELD

The present disclosure relates to memory devices, systems, and methods for program operations (also referred to as programming operations) in memory devices.

### BACKGROUND

Flash memory is a low-cost, high-density, nonvolatile solid-state storage medium that can be electrically erased and reprogrammed. Flash memory includes NOR flash memory and NAND flash memory. Various operations can be performed by a flash memory, for example, program operation, to change the threshold voltage of each memory cell to a respective level.

### SUMMARY

The present disclosure relates to memory devices, systems, and methods for program operations in memory devices.

Certain aspects of the subject matter described here can be implemented as a memory device.

One aspect of the present disclosure features a method of programming operation of a first memory cell. The method includes a prepare phase, a boosting phase, a program phase, and a recovery phase, where the boosting phase includes; applying a first boost voltage to a first word line coupled to the first memory cell; applying a second boost voltage to one or more second word lines, where each of the one or more second word lines is coupled to a respective second memory cell, and where the one or more second word lines are adjacent to the first word line; and where the program phase includes a first pulse phase and a second pulse phase, where, during the first pulse phase, the method includes: applying a first pulse voltage to the first word line, where the first pulse voltage is greater than the first boost voltage; applying a second pulse voltage to the one or more second word lines; and where, during the second pulse phase, the method includes: applying a third pulse voltage to one or more second word lines, where the third pulse voltage is greater than the second pulse voltage; and floating the first word line, where a voltage of the first word line is increased from the first pulse voltage to a fourth pulse voltage.

In some implementations, the first boost voltage is higher than the second boost voltage during the boosting phase.

In some implementations, a first delta voltage is a difference between the fourth pulse voltage and the first pulse voltage, and where a range of the first delta voltage is 0.5V-1.2V.

In some implementations, floating the first word line includes cutting off a control transistor coupled to the first word line, where the first word line and a voltage source are coupled together through the control transistor.

In some implementations, the method further includes recoupling the first memory cell and the voltage source by enabling the control transistor coupled to the first word line after the second pulse phase; and during the recovery phase, ramping down the fourth pulse voltage of the first word line and the third pulse voltages of the one or more second word lines.

In some implementations, the fourth pulse voltage of the first word line is ramping down through the voltage source with a two-step ramping process, where a first step of the two-step ramping process reduces the fourth pulse voltage of the first word line to an intermediate voltage and a second step of the two-step ramping process reduces the intermediate voltage of the first word line to a recovery voltage.

In some implementations, the one or more second word lines include a third word line coupled to a programmed memory cell and a fourth word line coupled to an unprogrammed memory cell, and where the method further includes: during the second pulse phase, increasing a value of the second pulse voltage of the third word line by a second delta voltage; and increasing a value of the second pulse voltage of the fourth word line by a third delta voltage.

In some implementations, the second delta voltage is corresponding to a programmed level of the programmed memory cell, and where the third delta voltage is greater than the second delta voltage.

In some implementations, a value of the second boost voltage is increased by a fourth delta voltage during the boosting phase, and a value of the second pulse voltage is increased by a fourth delta voltage during the first pulse phase as a number of program loops is greater than a threshold number.

In some implementations, a value of the second delta voltage and a value of the third delta voltage are decreased as the number of the program loops is greater than the threshold number during the second pulse phase.

Another aspect of the present disclosure features a memory device. The memory device includes a memory cell array; and a peripheral circuit coupled to the memory cell array and configured to perform a programming operation of a first memory cell in the memory device, the programming operation including a prepare phase, a boosting phase, a program phase, and a recovery phase, where the boosting phase includes: applying a first boost voltage to a first word line coupled to the first memory cell; applying a second boost voltage to one or more second word lines, where each of the one or more second word lines is coupled to a respective second memory cell, and where the one or more second word lines are adjacent to the first word line; and where the program phase includes a first pulse phase and a second pulse phase, where the first pulse phase includes: applying a first pulse voltage to the first word line, where the first pulse voltage is greater than the first boost voltage; applying a second pulse voltage to the one or more second word lines; and where the second pulse phase includes: applying a third pulse voltage to one or more second word lines, where the third pulse voltage is greater than the second pulse voltage; and floating the first word line, where a voltage of the first word line is increased from the first pulse voltage to a fourth pulse voltage.

In some implementations, the first boost voltage is higher than the second boost voltage during the boosting phase.

In some implementations, a first delta voltage is a difference between the fourth pulse voltage and the first pulse voltage, and where a range of the first delta voltage is 0.5V-1.2V.

In some implementations, floating the first word line includes cutting off a control transistor coupled to the first word line, where the first word line and a voltage source are coupled together through the control transistor.

In some implementations, the peripheral circuit is further configured to recouple the first word line and the voltage source by enabling the control transistor coupled to the first word line after the second pulse phase; and during the recovery phase, ramp down the fourth pulse voltage of the first word line and the third pulse voltages of the one or more second word lines.

In some implementations, the one or more second word lines include a third word line coupled to a programmed memory cell and a fourth word line coupled to an unprogrammed memory cell, and where peripheral circuit is further configured to: during the second pulse phase, ramp up a value of the second pulse voltage of the third word line by a second delta voltage; and ramp up a value of the second pulse voltage of the fourth word line by a third delta voltage.

In some implementations, the second delta voltage is corresponding to a programmed level of the programmed memory cell, and where the third delta voltage is greater than the second delta voltage.

In some implementations, a value of the second boost voltage is increased by a fourth delta voltage during the boosting phase, and a value of the second pulse voltage is increased by a fourth delta voltage during the first pulse phase as a number of program loops is greater than a threshold number.

In some implementations, a value of the second delta voltage and a value of the third delta voltage are decreased as the number of the program loops is greater than the threshold number during the second pulse phase.

A further aspect of the present disclosure features a memory system. The memory system includes a memory device and a memory controller coupled to the memory device and configured to control the memory device. The memory device includes a memory cell array; and a peripheral circuit coupled to the memory cell array and configured to perform a programming operation of a first memory cell in the memory device, the programming operation including a prepare phase, a boosting phase, a program phase, and a recovery phase, where the boosting phase includes: applying a first boost voltage to a first word line coupled to the first memory cell; applying a second boost voltage to one or more second word lines, where each of the one or more second word lines is coupled to a respective second memory cell, and where the one or more second word lines are adjacent to the first word line; and where the program phase includes a first pulse phase and a second pulse phase, where the first pulse phase includes: applying a first pulse voltage to the first word line, where the first pulse voltage is greater than the first boost voltage; applying a second pulse voltage to the one or more second word lines; and where the second pulse phase includes: applying a third pulse voltage to one or more second word lines, where the third pulse voltage is greater than the second pulse voltage; and floating the first word line, where a voltage of the first word line is increased from the first pulse voltage to a fourth pulse voltage.

The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates an example of a schematic circuit diagram of a memory device including peripheral circuits, according to some aspects of the present disclosure.

FIG. 2 illustrates an example of a side view of cross-sections of a memory cell array including NAND memory strings, according to some aspects of the present disclosure.

FIG. 3 illustrates an example of transactions between a host and a device, according to some aspects of the present disclosure.

FIG. 4A illustrates an example circuit schematic of an example word line driver, according to some aspects of the present disclosure.

FIG. 4B illustrates an example circuit schematic of a voltage supply circuit, according to some aspects of the present disclosure.

FIGS. 5A-5D illustrate example voltages of components in a memory cell array during a program operation of a memory cell in the memory cell array, according to some aspects of the present disclosure.

FIG. 6 illustrates an example of a flow chart of a process of an example program operation of a memory cell in a memory cell array, according to some aspects of the present disclosure.

FIG. 7 illustrates a block diagram of an example system having a memory device, according to some aspects of the present disclosure.

FIG. 8A illustrates a diagram of a memory card having a memory device, according to some aspects of the present disclosure.

FIG. 8B illustrates a diagram of a solid-state drive (SSD) having a memory device, according to some aspects of the present disclosure.

Like reference numbers and designations in the various drawings indicate like elements.

### DETAILED DESCRIPTION

Due to the demand for cheaper memory devices with higher density, a memory device (e.g., a 3D NAND flash memory) can be formed with a large number of layers and a high aspect ratio. The large number of layers and the high aspect ratio of such memory devices may present challenges during the programming operation of a memory cell. For example, a voltage value above the maximum voltage of the voltage source is required to be applied to the selected word line coupled to the memory cell when programming high levels of a polarity of levels of programming levels to a memory cell. The high voltage is achieved through a coupling effect from word lines adjacent to the selected word line. The connection between the voltage source and the selected word line during the programming phase may lead to current backflow to the voltage source. The current backflow may cause damages to the voltage source and reduce the applied voltage of the selected word line, thus increasing the programming pulse period.

In some cases, a program operation performed on a memory cell can include a prepare phase, a boosting phase, a program phase, and a recovery phase. During the boosting phase, a first boost voltage is applied to a first word line coupled to the first memory cell and a second boost voltage is applied to one or more second word lines, where each of the one or more second word lines is coupled to a respective second memory cell, and where the one or more second word lines are adjacent to the first word line. The program phase of the program operation of the memory call includes a first pulse voltage and a second pulse phase. During the first pulse phase, a first pulse voltage is applied to the first word line, where the first pulse voltage is greater than the first boost voltage, and a second pulse voltage is applied to the one or more second word lines. During the second pulse phase, a third pulse voltage is applied to one or more second word lines, where the third pulse voltage is greater than the second pulse voltage, and the first word line is floated, where a voltage of the first word line is increased from the first pulse voltage to a fourth pulse voltage.

Implementations of the present disclosure can provide one or more of the following technical effects. For example, during the second pulse phase of the programming phase, the selected word line is floated from the voltage source, and the increase in the applied pulse voltage is achieved through the coupling effect from the adjacent word lines. The floating of the selected word line separates it from the voltage source, which mitigates the effect of current backflow when the applied voltage on the selected word line is above the maximum voltage of the voltage source. In other words, the floating of the selected word line during the second pulse phase of the programming operation avoids damage to the voltage source. Additionally, the floating of the selected word line also assists in maintaining the high voltage in the selected word line during the second pulse phase, which leads to a reduction of the programming pulse period, which improves the efficiency of the programming operation.

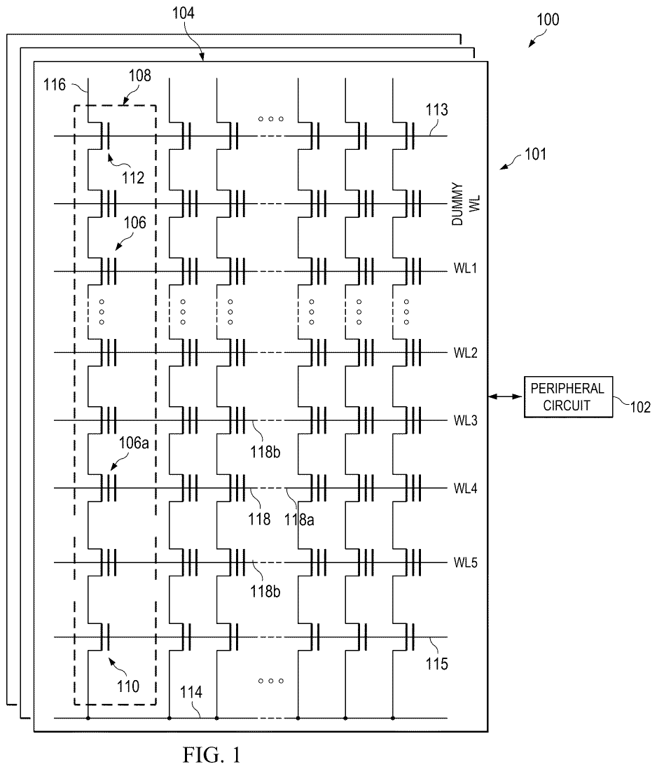

FIG. 1 illustrates an example of a schematic circuit diagram of a memory device 100 including peripheral circuits, according to some aspects of the present disclosure. Memory device 100 can include a memory cell array 101 and peripheral circuits 102 coupled to memory cell array 101. Memory cell array 101 can be a NAND Flash memory cell array in which memory cells 106 are provided in the form of an array of NAND memory strings 108 each extending vertically above a substrate (not shown). In some implementations, each NAND memory string 108 includes a plurality of memory cells 106 coupled in series and stacked vertically. Each memory cell 106 can hold a continuous, analog value, such as an electrical voltage or charge that depends on the number of electrons trapped within a region of memory cell 106. Each memory cell 106 can be either a floating gate type of memory cell including a floating-gate transistor or a charge trap type of memory cell including a charge-trap transistor.

In some implementations, each memory cell 106 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 106 is a multi-level cell (MLC) that is capable of storing more than a single bit of data in more than four memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 1 each NAND memory string 108 can include a source select gate (SSG) 110 at its source end and a drain select gate (DSG) 112 at its drain end. SSG 110 and DSG 112 can be configured to activate selected NAND memory strings 108 (columns of the array) during read and program operations. In some implementations, the sources of NAND memory strings 108 in the same block 104 are coupled through a same source line (SL) 114, e.g., a common SL. In other words, all NAND memory strings 108 in the same block 104 have an array common source (ACS), according to some implementations. DSG 112 of each NAND memory string 108 is coupled to a respective bit line 116 from which data can be read or written via an output bus (not shown), according to some implementations. In some implementations, each NAND memory string 108 is configured to be selected or deselected by applying a select voltage or a deselect voltage (e.g., 0 V) to respective DSG 112 through one or more DSG lines 113, and/or by applying a select voltage or a deselect voltage (e.g., 0 V) to respective SSG 110 through one or more SSG lines 115.

As shown in FIG. 1, NAND memory strings 108 can be organized into multiple blocks 104, each of which can have a common source line 114, e.g., coupled to the ACS. In some implementations, each block 104 is the basic data unit for erase operations, i.e., all memory cells 106 on the same block 104 are erased at the same time. To erase memory cells 106 in a selected block 104, source lines 114 coupled to selected block 104 as well as unselected blocks 104 in the same plane as selected block 104 can be biased with an erase voltage (Vers), such as a high positive voltage (e.g., 20 V or more). In some examples, erase operation may be performed at a half-block level, a quarter-block level, or a level having any suitable number of blocks or any suitable fractions of a block. Memory cells 106 of adjacent NAND memory strings can be coupled through word lines 118 that select which row of memory cells 106 is affected by read and program operations. Each word line 118 can include a plurality of control gates (gate electrodes) at each memory cell 106 and a gate line coupling the control gates. Example word lines (WLs) shown in FIG. 1 include dummy WL, WL1, WL2, WL3, WL4, and WL5 that are between one or more DSG lines 113 and one or more SSG lines 115.

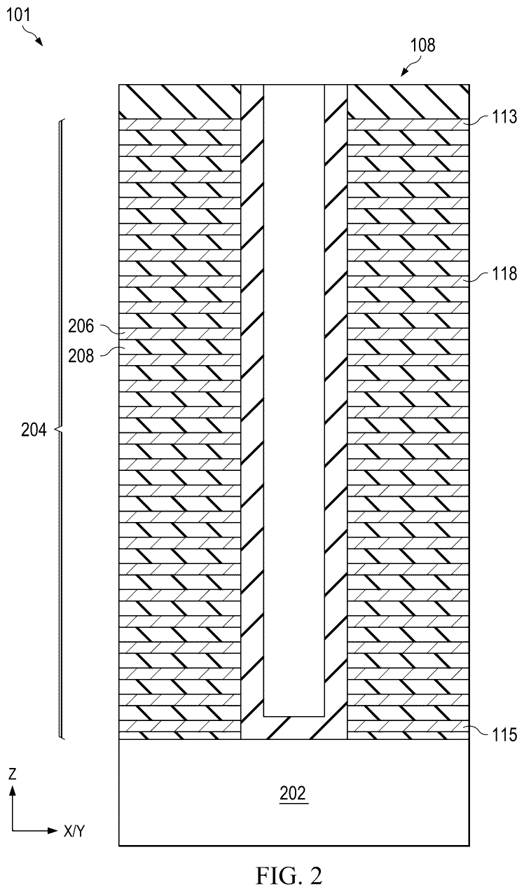

FIG. 2 illustrates an example of a side view of cross-sections of a memory cell array 101 including NAND memory strings 108, according to some aspects of the present disclosure. As shown in FIG. 2, NAND memory string 108 can extend vertically through a memory stack 204 above a substrate 202. Substrate 202 can include silicon (e.g., single crystalline silicon), silicon germanium (SiGe), gallium arsenide (GaAs), germanium (Ge), silicon on insulator (SOI), germanium on insulator (GOI), or any other suitable materials.

Memory stack 204 can include interleaved gate conductive layers 206 and gate-to-gate dielectric layers 208. The number of the pairs of gate conductive layers 206 and gate-to-gate dielectric layers 208 in memory stack 204 can determine the number of memory cells 106 in memory cell array 101. Gate conductive layer 206 can include conductive materials including, but not limited to, tungsten (W), cobalt (Co), copper (Cu), aluminum (Al), polysilicon, doped silicon, silicides, or any combination thereof. In some implementations, each gate conductive layer 206 includes a metal layer, such as a tungsten layer. In some implementations, each gate conductive layer 206 includes a doped polysilicon layer. Each gate conductive layer 206 can include control gates surrounding the memory cells 106, DSG 112, or SSG 110, and can extend laterally as DSG line 113 at the top of memory stack 204, SSG line 115 at the bottom of memory stack 204, or word line 118 between DSG line 113 and SSG line 115.

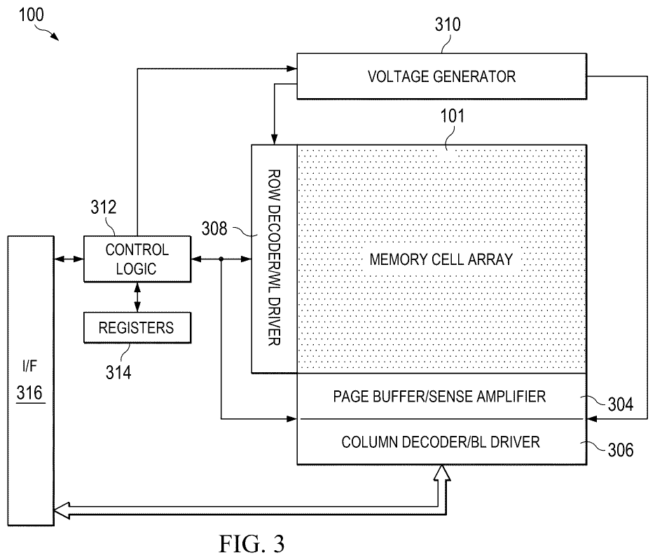

Peripheral circuits 102 can be coupled to memory cell array 101 through bit lines 116, word lines 118, source lines 114, SSG lines 115, and DSG lines 113. Peripheral circuits 102 can include any suitable analog, digital, and mixed-signal circuits for facilitating the operations of memory cell array 101 by applying and sensing voltage signals and/or current signals to and from each target memory cell of the memory cells 106 through bit lines 116, word lines 118, source lines 114, SSG lines 115, and DSG lines 113. Peripheral circuits 102 can include various types of peripheral circuits formed using metal-oxide-semiconductor (MOS) technologies. For example, FIG. 3 illustrates some example peripheral circuits, according to some aspects of the present disclosure. The example peripheral circuits include a page buffer/sense amplifier 304, a column decoder/bit line driver 306, a row decoder/word line driver 308, a voltage generator 310, control logic 312, registers 314, an interface 316, and a data bus. In some examples, additional peripheral circuits not shown in FIG. 3 may be included as well.

Page buffer/sense amplifier 304 can be configured to read and program (write) data from and to memory cell array 101 according to the control signals from control logic 312. In one example, page buffer/sense amplifier 304 may store one page of program data (write data) to be programmed into one page of memory cell array 101. In another example, page buffer/sense amplifier 304 may perform program verify operations to ensure that the data has been properly programmed into memory cells 106 coupled to selected word lines 118. In still another example, page buffer/sense amplifier 304 may also sense the low power signals from bit line 116 that represents a data bit stored in memory cell 106 and amplify the small voltage swing to recognizable logic levels in a read operation. Column decoder/bit line driver 306 can be configured to be controlled by control logic 312 and select one or more NAND memory strings 108 by applying bit line voltages generated from voltage generator 310.

Row decoder/word line driver 308 can be configured to be controlled by control logic 312 and select/deselect blocks 104 of memory cell array 101 and select/deselect word lines 118 of block 104. Row decoder/word line driver 308 can be further configured to drive word lines 118 using word line voltages generated from voltage generator 310. In some implementations, row decoder/word line driver 308 can also select/deselect and drive SSG lines 115 and DSG lines 113 as well. Row decoder/word line driver 308 can be configured to apply a read voltage to selected word line 118 in a read operation on memory cell 106 coupled to selected word line 118.

Voltage generator 310 can be configured to be controlled by control logic 312 and generate the word line voltages (e.g., read voltage, program voltage, pass voltage, local voltage, verification voltage, etc.), bit line voltages, and source line voltages to be supplied to memory cell array 101.

Control logic 312 can be coupled to each peripheral circuit described above and configured to control operations of each peripheral circuit. Registers 314 can be coupled to control logic 312 and include status registers, command registers, and address registers for storing status information, command operation codes (OP codes), and command addresses for controlling the operations of each peripheral circuit. The status registers of registers 314 can include one or more registers configured to store open block information indicative of the open block(s) of all blocks 104 in memory cell array 101, such as having an auto dynamic start voltage (ADSV) list. In some implementations, the open block information is also indicative of the last programmed page of each open block.

Interface 316 can be coupled to control logic 312 and act as a control buffer to buffer and relay control commands received from a host (not shown) to control logic 312 and status information received from control logic 312 to the host. Interface 316 can also be coupled to column decoder/bit line driver 306 via a data bus and act as a data input/output (I/O) interface and a data buffer to buffer and relay the data to and from memory cell array 101.

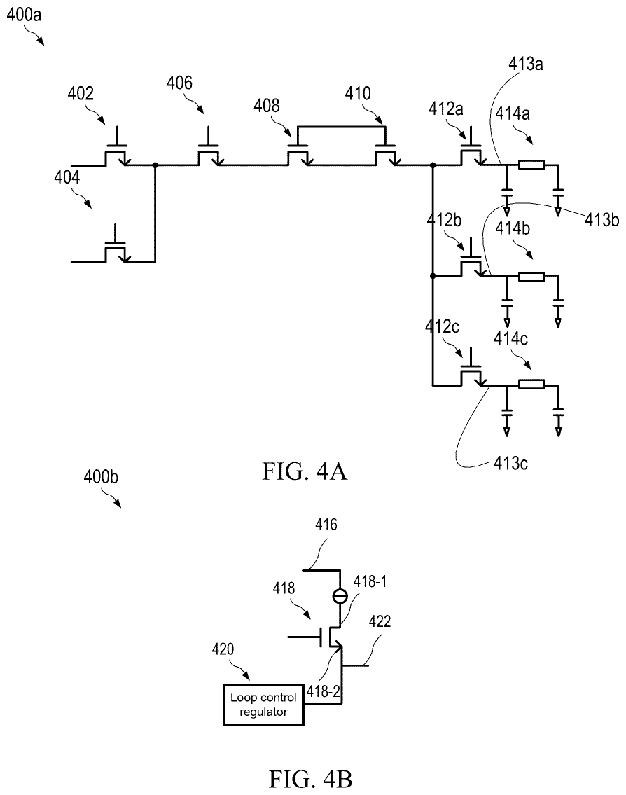

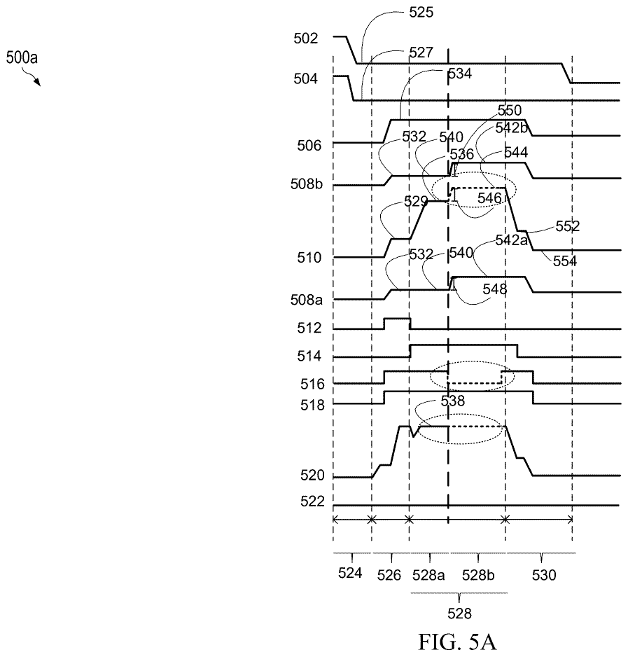

FIG. 4A illustrates example circuit diagram of a word line driver 400a, according to some aspects of the present disclosure. In some implementations, the word line driver 400a can be the row decoder/word line driver 308 in FIG. 3. The word line driver 400a can include a pulse transistor 402 coupled to the voltage source and a boost transistor 404 coupled to the boost power source. The pulse transistor 402 and the boost transistor 404 are configured to control the applied voltage on word lines during operations. The word line driver 400a can also include a control transistor 406, where the voltage sources and the word lines are coupled together through the control transistor. In some implementations, as shown in FIG. 4A, the word line driver 400a can include global word line select transistors 408 and 410 configured to select corresponding word lines coupled to the memory cell array. Each word lines of the memory cell array are coupled to the voltage source through a row decoder/word line driver 412. The row decoder/word line driver 412 can be an implementation of the row decoder/word line driver 308 of FIG. 3. A circuit 414a represents an equivalent circuit for memory cells coupled to the word line 413a. The circuits 414a can include two capacitors connected in parallel and a resistor connected in series with one of the capacitors coupled to a word line 413 a. Similarly, circuits 414b and 414c can represent equivalent circuits for memory cells coupled to the word lines 413b and 413c, respectively. For example, a first word line 413b is coupled to the voltage source through the row decoder/word line driver 412b and one or more second word liens 413a, 413c adjacent to the first word line 413b are coupled to the row decoder/word line drivers 412a and 412c adjacent to the row decoder/word line driver 412b. The number of the row decoder/word line drivers 412, word lines 413, and circuits 414 coupled to the word lines 413 in FIG. 4A is for illustration only and that any suitable number of the row decoder/word line drivers 412 can be included in the word line driver 400a.

FIG. 4B illustrates an example circuit schematic of a voltage supply circuit 400b, according to some aspects of the present disclosure. As shown in FIG. 4B, a voltage source is connected to a first terminal 418-1 of a power supply transistor 418 through a line 416. A second terminal 418-2 of the power supply transistor 418 is connected to the loop control regulator 420, where the loop control regulator is configured to control the power supply transistor 418 and apply the source voltage to the word line driver 400a when the power supply transistor 418 is turned on. The voltage supply circuit 400b is coupled to the word line driver 400a through a line 422.

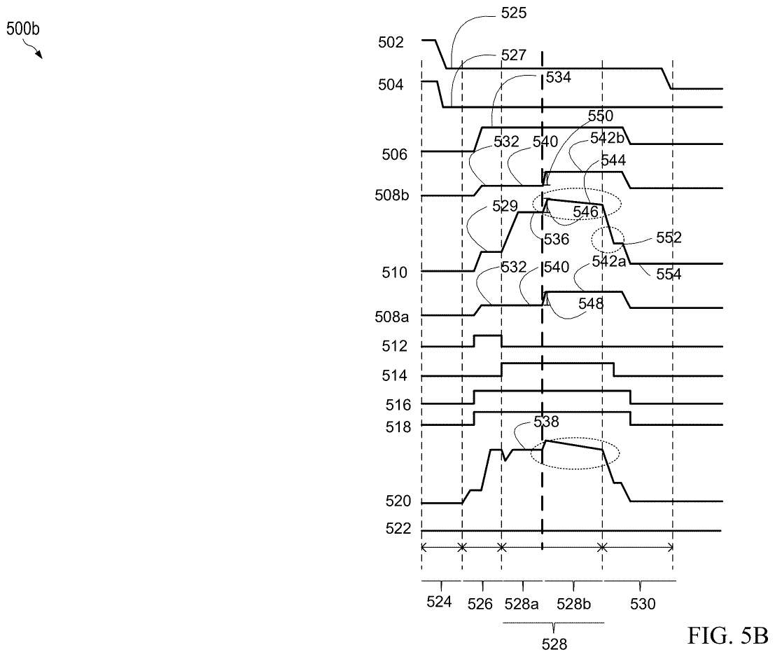

FIG. 5A illustrates an example of components in a memory cell array during a program operation 500a of a memory cell in the memory cell array, according to some aspects of the present disclosure. In some implementations, selTSG 502 represents a select gate line, for example, DSG line 113, coupled to one or more select gate transistors, for example, DSG 112 (e.g., first select gate transistor) in FIG. 1. UnselTSG 504 represents a select gate line that is turned off. In some implementations, a first word line 510 represents the first word line selected for a program operation. The first word line 510 can be an example of word line 118 in FIG. 1. One or more second word lines 508 represent the one or more second word lines adjacent to the first word line selected for the program operation. The one or more second word lines 508 can be examples of word line 118 in FIG. 1. Remaining word lines 506 represents the remaining word lines except the first word line or the one or more second word lines. The remaining word lines 506 can be examples of word line 118 in FIG. 1. G_boost 512 represents a signal of the boost transistor 404 configured to control the boost power source, where the boost power source is applied to the word line driver 400a when the pulse transistor 402 is turned on and voltage is applied to the word line from the boost power source. G_pulse 514 represents a signal of the pulse transistor 402 configured to control the voltage source, where a source voltage of the voltage source is applied to the word line driver 400a when the boost transistor 404 is turned on and voltage is applied to the word line from the voltage source. G_vzone 516 represents a signal of the control transistor 406, where the word lines are coupled to the voltage source when the control transistor 406 is turned on. G_sel 518 represents the global select transistors 408, 410, where a memory cell of the memory cell array is selected for the program operation when the global select transistors 408, 410 are turned on. SourceV 520 represents a voltage value in the voltage source that is applied to word lines during the program operation. BSG 522 represents a bottom select gate line, for example, SSG line 115, that is coupled to one or more select gate transistors, for example, SSG 110 (e.g., source select gate transistor) in FIG. 1.

In some implementations, as shown in FIG. 5A, the program operation of a first memory cell coupled to the first word line includes a prepare phase 524, a boosting phase 526, a program phase 528, and a recovery phase 530. In some implementations, the prepare phase 524 prepares a first memory cell coupled to the first word line 510 for program operation by turn on a select gate line corresponding the first memory cell. The boosting phase 526 applies a first voltage to the first word line 510 to assist voltage ramps up and reduce the time for program phase 528. The program phase 528 ramps up the first voltage to the target voltage applied to the first word line 510 to program the first memory cell to a target program level of a plurality of programming levels, where the second voltage is higher than the first voltage. The recovery phase 530 ramps down the second voltage applied to the first word line 510 to a recovery voltage.

In some implementations, during the prepare phase 524 of the program operation 500a, a voltage in the selTSG 502 decreases to a first prepare voltage 525, and a voltage in the unselTSG 504 decreases to a second prepare voltage 527. An example value of the first prepare voltage 525 is 3V. An example of the second prepare voltage is Vss as shown in FIG. 5A, where an example of Vss is 0V. In some implementations, during the prepare phase 524, the second prepare voltage 527 is applied to the first word line 510, the second word line 508, and the remaining word lines 506.

In some implementations, during the boosting phase 526 of the program operation 500a, a first boost voltage 529 is applied to the first word line 510, a second boost voltage 532 is applied to the one or more second word lines 508, and a third boost voltage 534 is applied to the remaining word lines 506. An example first boost voltage 529 is 6.5V, an example second boost voltage 532 is 3V and a range of the third boost voltage 534 is from 6V to 10V. In some implementations, a value of the first boost voltage 529 is higher than a value of the second boost voltage 532 during the boosting phase 526.

In some implementations, the program phase 528 of the program operation 500a includes a first pulse phase 528a and a second pulse phase 528b. In some implementations, during the first pulse phase 528a, a first pulse voltage 536 is applied to the first word line 510, where the first pulse voltage 536 is greater than the first boost voltage 529. In some implementations, a value of the first pulse voltage 536 is equal to a value of a source voltage 538 of the voltage source during the first pulse phase 528a as shown by the SourceV 520 in FIG. 5A. An example of the source voltage 538 during the first pulse phase 528a is Vpe as shown in FIG. 5A, where an example of Vpe is in a range of 15V to 25V. In some implementations, a second pulse voltage 540 is applied to the one or more second word lines 508. In some implementations, a value of the second pulse voltage 540 is equal to a value of the second boost voltage 532.

In some implementations, during the second pulse phase 528b, a third pulse voltage 542 is applied to one or more second word lines 508, where the third pulse voltage 542 is greater than the second pulse voltage 540. In some implementations, the first word line 510 and the voltage source are coupled together through the control transistor 406. During the second pulse phase 528b, the first word line 510 is floated from the voltage source by cutting off the control transistor 406. A value of the voltage applied to the first word line 510 is increased from the first pulse voltage 536 voltage to a fourth pulse voltage 544 due to the coupling effect from the third pulse voltage 542 applied to the one or more second word lines 508. In some implementations, the increase of the first pulse voltage 536 can lead to a reduce pulse width for the second pulse phase 528b, which results in a reduction of the programming time of the memory cell coupled to the first word line 510. In some implementations, during the second pulse phase 528b, a first delta voltage 546 is a difference between the fourth pulse voltage 544 and the first pulse voltage 536, where a range of the first delta voltage is from 0.5 V to 1.2V.

In some implementations, after the second pulse phase 528b, the first word line 510 line and the voltage source are recoupled together by enabling the control transistor 406. For example, as shown in FIG. 5A, the enabling of the control transistor 406 is shown by tunning on the G_vzone 516 at the end of the second pulse phase 528b. In some implementations, the one or more second word lines 508 include a third word line 508a coupled to a programmed memory cell and a fourth word line 508b coupled to an unprogrammed memory cell. During the second pulse phase 528b, a value of voltage applied to the third word line 508a ramps up by a second delta voltage 548 and a value of voltage applied to the fourth word line 508b ramps up by a third delta voltage 550. In some implementations, the second delta voltage 548 corresponding to a programmed level of the programmed memory cell, and the third delta voltage 550 is greater than the second delta voltage 548.

In some implementations, during the recovery phase 530 of the program operation 500a, a value of voltage applied to the first word line 510 ramps down from the fourth pulse voltage 544 through the voltage source by a two-step ramping process. A first step of the two-step ramping process reduces the fourth pulse voltage 544 of the first word line 510 to an intermediate voltage 552, and a second step of the two-step ramping process reduces the intermediate voltage 552 of the first word line 510 to a recovery voltage 554. An example of the recovery voltage 554 is vdd as shown in FIG. 5A, where one example of the vdd is 0V. An example of the intermediate voltage 552 is 8V. In some implementations, a value of voltage applied to the one or more second word lines 508 ramps down from the third pulse voltage 542 to the recovery voltage 554. For example, as shown in FIG. 5A, during the recovery phase 530, the signal of G_vzone 516 is high indicating the first word line 510 and the voltage source are coupled together through the control transistor 406. During the first step of the two-step ramping process, the fourth pulse voltage 544 of the first word line 510 is ramping down with the sourceV 520 to an intermediate voltage 522 (e.g., 8V as shown in FIG. 5A). The reduction of the fourth pulse voltage 544 of the first word line 510 during the first step of the two-step ramping process is due to a strong discharge effect of the voltage source. During the second step of the two-step ramping process, the voltage source pulls down the intermediate voltage 522 of the first word line 510 to a recovery voltage 554 (e.g., vdd as shown in FIG. 5A) by the strong discharge effect.

FIG. 5B illustrates another example of components in a memory cell array during a program operation 500b of a memory cell in the memory cell array, according to some aspects of the present disclosure. Voltage conditions of most components of the memory cell block are identical to those in FIG. 5A, except for the first word line 510 and the SourceV 520.

In some implementations, as shown in FIG. 5B, the first word line 510 and the voltage source remains coupled to each other during the second pulse phase 528b of the program operation 500b. A value of the voltage applied to the first word line 510 is increased from the first pulse voltage 536 voltage to a fourth pulse voltage 544 due to the coupling effect from the third pulse voltage 542 applied to the one or more second word lines 508 at a first portion of the second pulse phase 528b. The value of the voltage applied to the first word line 510 ramps down during a remaining portion of the second pulse phase 528b. In some implementations, the value of voltage applied to the first word line 510 is equal to a value of the voltage source during the second pulse phase 528b.

In some implementations, as shown in FIG. 5B, the first word line 510 and the voltage source remain coupled to each other through the transistor 406 during the second pulse phase 528b, as indicated by a high signal of the G_Vzone 516 in program operation 500b. The increase in the value of the voltage applied to the first word line 510 by the coupling effect from one or more second word lines 508 also causes an increase in the value of the voltage of the voltage source since the first word line 510 is coupled to the voltage source during the second pulse phase. Due to the strong discharge effect of the voltage source, the increased value of the voltage applied to the word line 510 is pulled down through the voltage source. In some implementations, the increase in the value of the voltage of the voltage source is above a maximum voltage limit (e.g., Vpe of FIG. 5B), which can apply high stress to the components of the voltage source and reduce its lifespan. In some implementations, as shown in FIG. 5A, the first word line 510 is floated from the voltage source by cutting off the control transistor 406, as indicated by a low signal of the G_Vzone 516 in program operation 500a. This prevents the value of the voltage source from increasing above the maximum voltage limit (as shown in FIG. 5B), which protects the voltage source during program operation 500a. In some implementations, floating the first word line 510 during the second pulse phase 528A also ensures that the value of the voltage applied to the first word line 510 remains at the fourth pulse voltage 544 during the second pulse phase 528b, which can reduce the programming time of the memory cell coupled to the first word line 510 in program operation 500a and improve programming efficiency.

In some implementations, the control logic 312 is configured to identify the number of program pulses during a program operation. FIG. 5C illustrates an example of voltages of some components in a memory cell array during a program operation 500c of a memory cell in the memory cell array, according to some aspects of the present disclosure, where a number of program pulses is below a threshold number. In some implementations, the threshold number of the program pluses is 12. As shown in FIG. 5C, voltage conditions for all components of the memory cell array are identical to those in FIG. 5A.

FIG. 5D illustrates an example of voltages of some components in a memory cell array during a program operation 500d of a memory cell in the memory cell array, according to some aspects of the present disclosure, where a number of program pulses is above the threshold number. In some implementations, the threshold number of the program pluses is 12. As shown in FIG. 5D, voltage conditions for most components of the memory cell array are identical to those in FIG. 5A, except for the third word line 508a and the fourth word line 508b. As shown in FIG. 5D, during the boosting phase 526 of the program operation 500d, a value of voltage applied to the third word line 508a and the fourth word line 508b increases from the second boost voltage 532 to a fourth boost voltage 533 at a number of program pulses above the threshold number. In some implementations, the difference between the fourth boost voltage 533 and the second boost voltage 532 is a fourth delta voltage. In some implementations, during the first pulse phase 528a of the program operation 500d, a value of voltage applied to the third word line 508a and the fourth word line 508b increases from the second pulse voltage 540 to a fifth pulse voltage 541 at a number of program pulses above the threshold number. In some implementations, a difference between the fifth pulse voltage 541 and the second pulse voltage 540 is the fourth delta voltage. In some implementations, a value of the fourth boost voltages 533 is equal to a value of the fifth pulse voltage 541. In some implementations, during the second pulse phase 528b of the program operation 500d, a value of the voltage applied to the third word line 508a increases from the fifth pulse voltage 541 to a sixth pulse voltage 543a by a fifth delta voltage 549. A value of the voltage applied to the fourth word line 508b is increased from the fifth pulse voltage 541 to a seventh pulse voltage 543b by a sixth delta voltage 551. In some implementations, a value of the fifth delta voltage 549 is lower than a value of the second delta voltage 548 and a value of the sixth delta voltage 551 is lower than a value of the third delta voltage 550.

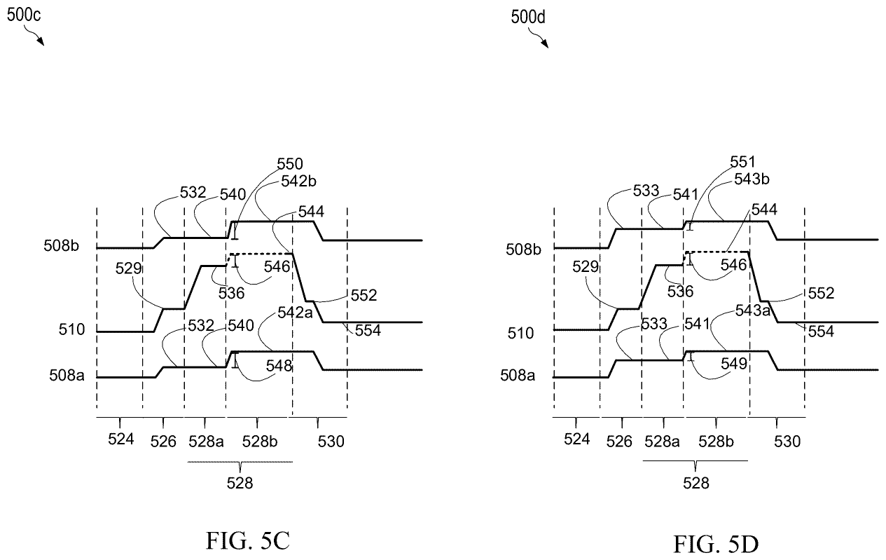

FIG. 6 illustrates an example of a flow chart of a process 600 of an example program operation of a memory cell in a memory cell array, according to some aspects of the present disclosure. The process 600 can be performed to program a first memory cell (e.g., memory cell 106a of FIG. 1) of a memory cell array (e.g., the memory cell array 101 of FIG. 1). It is understood that the operations shown in process 600 are not exhaustive and that other operations can be performed as well before, after, or between any of the illustrated operations. Further, some of the operations may be performed simultaneously, or in a different order than shown in FIG. 6.

At operation 602, program a first memory cell (e.g., memory cell 106 of FIG. 1) with a programming operation, where the programming operation includes a prepare phase (e.g., the prepare phase 524 of FIG. 5A), a boosting phase (e.g., the boosting phase 526 of FIG. 5A), a program phase (e.g., the program phase 528 of FIG. 5A), and a recovery phase (e.g., the recovery phase 530 of FIG. 5A).

At operation 604, during a boosting phase, apply a first boost voltage (e.g., the first boost voltage 529 of FIG. 5A) to a first word line (e.g., the first word line 510 of FIG. 5A) coupled to the first memory cell, and apply a second boost voltage (e.g., the second boost voltage 532 of FIG. 5A) to one or more second word lines, where each of the one or more second word lines (e.g., the one or more second word lines 508 of FIG. 5A) is coupled to a respective second memory cell, and where the one or more second word lines are adjacent to the first word line. For example, as shown in FIG. 1, the first word line 118a is positioned next to the second word lines 118b, and there are no other word line between the first word line 118a and each of the second word lines 118b At operation 606, during the first pulse phase of the program phase, apply a first pulse voltage (e.g., the first pulse voltage 536 of FIG. 5A) to the first word line, where the first pulse voltage is greater than the first boost voltage, and apply a second pulse voltage (e.g., the second pulse voltage 540 of FIG. 5A) to the one or more second word lines.

At operation 608, during the second pulse phase of the program phase, apply a third pulse voltage (e.g., the third pulse voltage 542 of FIG. 5A) to one or more second word lines, where the third pulse voltage is greater than the second pulse voltage, and float the first word line, where a voltage of the first word line is increased from the first pulse voltage to a fourth pulse voltage (e.g., the fourth pulse voltage 544 of FIG. 5A).

In some implementations, the first boost voltage is higher than the second boost voltage during the boosting phase.

In some implementations, a first delta voltage (e.g., the first delta voltage 546 of FIG. 5A) is a difference between the fourth pulse voltage and the first pulse voltage, and where a range of the first delta voltage is 0.5V-1.2V.

In some implementations, floating the first word line includes cutting off a control transistor (e.g., the control transistor 406 of FIG. 4A) coupled to the first word line, where the first word line and a voltage source are coupled together through the control transistor.

In some implementations, the process 600 further includes recoupling the first memory cell and the voltage source by enabling the control transistor coupled to the first word line after the second pulse phase; and during the recovery phase, ramping down the fourth pulse voltage of the first word line and the third pulse voltages of the one or more second word lines.

In some implementations, the fourth pulse voltage of the first word line is ramping down through the voltage source with a two-step ramping process, where a first step of the two-step ramping process reduces the fourth pulse voltage of the first word line to an intermediate voltage (e.g., the intermediate voltage 552 of FIG. 5A) and a second step of the two-step ramping process reduces the intermediate voltage of the first word line to a recovery voltage (e.g., the recovery voltage 554 of FIG. 5A).

In some implementations, the one or more second word lines include a third word line (e.g., the third word line 508a of FIG. 5A) coupled to a programmed memory cell and a fourth word line (e.g., the fourth word line 508b of FIG. 5A) coupled to an unprogrammed memory cell, and where the process 600 further include: during the second pulse phase, increasing a value of the second pulse voltage of the third word line by a second delta voltage (e.g., the second delta voltage 548 of FIG. 5A); and increasing a value of the second pulse voltage of the fourth word line by a third delta voltage (e.g., the third delta voltage 550 of FIG. 5A).

In some implementations, the second delta voltage is corresponding to a programmed level of the programmed memory cell, and where the third delta voltage is greater than the second delta voltage.

In some implementations, a value of the second boost voltage is increased by a fourth delta voltage during the boosting phase, and a value of the second pulse voltage is increased by a fourth delta voltage during the first pulse phase as a number of program loops is greater than a threshold number.

In some implementations, a value of the second delta voltage and a value of the third delta voltage are decreased as the number of the program loops is greater than the threshold number during the second pulse phase.

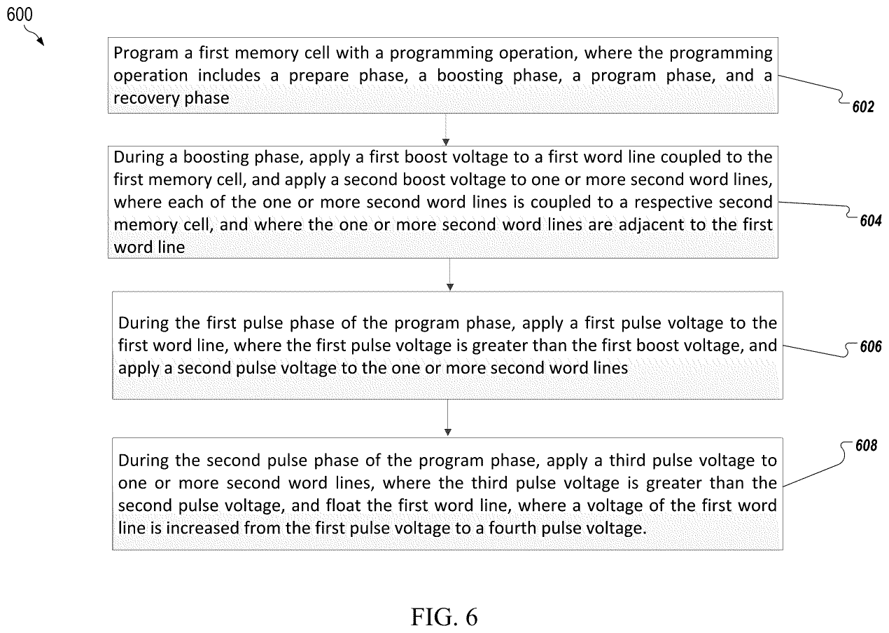

FIG. 7 illustrates a block diagram of an example system 700 having a memory device, according to some aspects of the present disclosure. System 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 7, system 700 can include a host 708 and a memory system 702 having one or more memory devices 704 and a memory controller 706. Host 708 can be a processor of an electronic device, such as a central processing unit (CPU), or a system-on-chip (SoC), such as an application processor (AP). Host 708 can be configured to send or receive data to or from memory devices 704.

Memory device 704 can be any memory device disclosed in the present disclosure. Memory controller 706 is coupled to memory device 704 and host 708 and is configured to control memory device 704, according to some implementations. Memory controller 706 can manage the data stored in memory device 704 and communicate with host 708. In some implementations, memory controller 706 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 706 is designed for operating in a high duty-cycle environment SSDs or embedded multi-media-cards (eMMCs) used as data storage for mobile devices, such as smartphones, tablets, laptop computers, etc., and enterprise storage arrays. Memory controller 706 can be configured to control operations of memory device 704, such as read, erase, and program operations. Memory controller 706 can also be configured to manage various functions with respect to the data stored or to be stored in memory device 704 including, but not limited to bad-block management, garbage collection, logical-to-physical address conversion, wear leveling, etc. In some implementations, memory controller 706 is further configured to process error correction codes (ECCs) with respect to the data read from or written to memory device 704. Any other suitable functions may be performed by memory controller 706 as well, for example, formatting memory device 704.

Memory controller 706 can communicate with an external device (e.g., host 708) according to a particular communication protocol. For example, memory controller 706 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

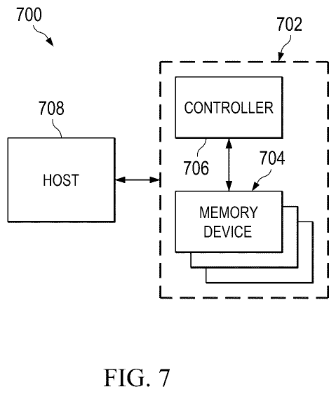

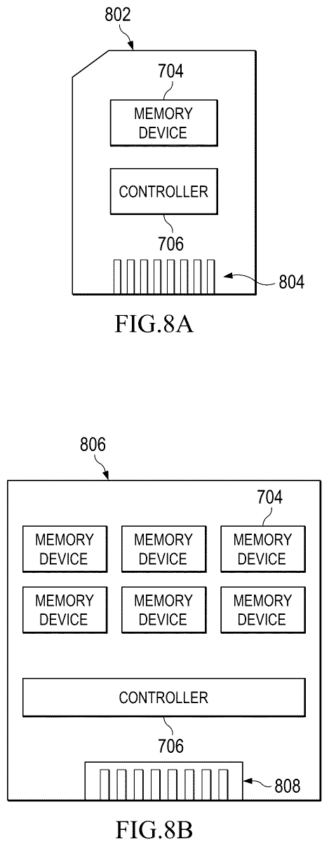

Memory controller 706 and one or more memory devices 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 8A, memory controller 706 and a single memory device 704 may be integrated into a memory card 802. Memory card 802 can include a PC card (PCMCIA, personal computer memory card international association), a CF card, a smart media (SM) card, a memory stick, a multimedia card (MMC, RS-MMC, MMCmicro) , an SD card (SD, miniSD, microSD, SDHC), a UFS, etc. Memory card 802 can further include a memory card connector 804 coupling memory card 802 with a host (e.g., host 708 in FIG. 6). In another example as shown in FIG. 8B, memory controller 706 and multiple memory devices 704 may be integrated into an SSD 806. SSD 806 can further include an SSD connector 808 coupling SSD 806 with a host (e.g., host 708 in FIG. 6). In some implementations, the storage capacity and/or the operation speed of SSD 806 is greater than those of memory card 802.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, the phraseology or terminology employed in this disclosure, and not otherwise defined, is for the purpose of description only and not of limitation. Any use of section headings is intended to aid reading of the document and is not to be interpreted as limiting; information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, such operations are not required be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations are not required in all implementations, and the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. A method of programming operation of a first memory cell, comprising:
a prepare phase, a boosting phase, a program phase, and a recovery phase, wherein the boosting phase comprises:
applying a first boost voltage to a first word line coupled to the first memory cell;
applying a second boost voltage to one or more second word lines, wherein each of the one or more second word lines is coupled to a respective second memory cell, and wherein the one or more second word lines are adjacent to the first word line; and
wherein the program phase comprises a first pulse phase and a second pulse phase, wherein, during the first pulse phase, the method comprises:
applying a first pulse voltage to the first word line, wherein the first pulse voltage is greater than the first boost voltage;
applying a second pulse voltage to the one or more second word lines; and
wherein, during the second pulse phase, the method comprises:
applying a third pulse voltage to one or more second word lines, wherein the third pulse voltage is greater than the second pulse voltage; and
floating the first word line, wherein a voltage of the first word line is increased from the first pulse voltage to a fourth pulse voltage.

2. The method of claim 1, wherein the first boost voltage is higher than the second boost voltage during the boosting phase.

3. The method of claim 1, wherein a first delta voltage is a difference between the fourth pulse voltage and the first pulse voltage, and wherein a range of the first delta voltage is 0.5V-1.2V.

4. The method of claim 1, wherein floating the first word line comprises:
cutting off a control transistor coupled to the first word line, wherein the first word line and a voltage source are coupled together through the control transistor.

5. The method of claim 4, further comprising:
recoupling the first memory cell and the voltage source by enabling the control transistor coupled to the first word line after the second pulse phase; and
during the recovery phase, ramping down the fourth pulse voltage of the first word line and the third pulse voltages of the one or more second word lines.

6. The method of claim 5, wherein the fourth pulse voltage of the first word line is ramping down through the voltage source with a two-step ramping process, wherein a first step of the two-step ramping process reduces the fourth pulse voltage of the first word line to an intermediate voltage and a second step of the two-step ramping process reduces the intermediate voltage of the first word line to a recovery voltage.

7. The method of claim 1, wherein the one or more second word lines comprise a third word line coupled to a programmed memory cell and a fourth word line coupled to an unprogrammed memory cell, and wherein the method further comprises:
during the second pulse phase, increasing a value of the second pulse voltage of the third word line by a second delta voltage; and
increasing a value of the second pulse voltage of the fourth word line by a third delta voltage.

8. The method of claim 7, wherein the second delta voltage is corresponding to a programmed level of the programmed memory cell, and wherein the third delta voltage is greater than the second delta voltage.

9. The method of claim 7, wherein a value of the second boost voltage is increased by a fourth delta voltage during the boosting phase, and a value of the second pulse voltage is increased by a fourth delta voltage during the first pulse phase as a number of program loops is greater than a threshold number.

10. The method of claim 9, wherein a value of the second delta voltage and a value of the third delta voltage are decreased as the number of the program loops is greater than the threshold number during the second pulse phase.

11. A memory device comprising:
a memory cell array; and
a peripheral circuit coupled to the memory cell array and configured to perform a programming operation of a first memory cell in the memory device, the programming operation comprising:
a prepare phase, a boosting phase, a program phase, and a recovery phase, wherein the boosting phase comprises:
applying a first boost voltage to a first word line coupled to the first memory cell;
applying a second boost voltage to one or more second word lines, wherein each of the one or more second word lines is coupled to a respective second memory cell, and wherein the one or more second word lines are adjacent to the first word line; and
wherein the program phase comprises a first pulse phase and a second pulse phase, wherein the first pulse phase comprises:
applying a first pulse voltage to the first word line, wherein the first pulse voltage is greater than the first boost voltage;
applying a second pulse voltage to the one or more second word lines; and
wherein the second pulse phase comprises:
applying a third pulse voltage to one or more second word lines, wherein the third pulse voltage is greater than the second pulse voltage; and
floating the first word line, wherein a voltage of the first word line is increased from the first pulse voltage to a fourth pulse voltage.

12. The memory device of claim 11, wherein the first boost voltage is higher than the second boost voltage during the boosting phase.

13. The memory device of claim 11, wherein a first delta voltage is a difference between the fourth pulse voltage and the first pulse voltage, and wherein a range of the first delta voltage is 0.5V-1.2V.

14. The memory device of claim 11, wherein floating the first word line comprises:
cutting off a control transistor coupled to the first word line, wherein the first word line and a voltage source are coupled together through the control transistor.

15. The memory device of claim 14, wherein the peripheral circuit is further configured to:
recouple the first word line and the voltage source by enabling the control transistor coupled to the first word line after the second pulse phase; and
during the recovery phase, ramp down the fourth pulse voltage of the first word line and the third pulse voltages of the one or more second word lines.

16. The memory device of claim 11, wherein the one or more second word lines comprise a third word line coupled to a programmed memory cell and a fourth word line coupled to an unprogrammed memory cell, and wherein peripheral circuit is further configured to:
during the second pulse phase, ramp up a value of the second pulse voltage of the third word line by a second delta voltage; and
ramp up a value of the second pulse voltage of the fourth word line by a third delta voltage.

17. The memory device of claim 16, wherein the second delta voltage is corresponding to a programmed level of the programmed memory cell, and wherein the third delta voltage is greater than the second delta voltage.

18. The memory device of claim 16, wherein a value of the second boost voltage is increased by a fourth delta voltage during the boosting phase, and a value of the second pulse voltage is increased by a fourth delta voltage during the first pulse phase as a number of program loops is greater than a threshold number.

19. The memory device of claim 18, wherein a value of the second delta voltage and a value of the third delta voltage are decreased as the number of the program loops is greater than the threshold number during the second pulse phase.

20. A memory system, comprising:
a memory device; and
a memory controller coupled to the memory device and configured to control the memory device,
wherein the memory device comprises:
a memory cell array; and
a peripheral circuit coupled to the memory cell array and configured to perform a programming operation of a first memory cell in the memory device, the programming operation comprising:
a prepare phase, a boosting phase, a program phase, and a recovery phase, wherein the boosting phase comprises:
applying a first boost voltage to a first word line coupled to the first memory cell;
applying a second boost voltage to one or more second word lines, wherein each of the one or more second word lines is coupled to a respective second memory cell, and wherein the one or more second word lines are adjacent to the first word line; and
wherein the program phase comprises a first pulse phase and a second pulse phase, wherein the first pulse phase comprises:
applying a first pulse voltage to the first word line, wherein the first pulse voltage is greater than the first boost voltage;
applying a second pulse voltage to the one or more second word lines; and
wherein the second pulse phase comprises:
applying a third pulse voltage to one or more second word lines, wherein the third pulse voltage is greater than the second pulse voltage; and
floating the first word line, wherein a voltage of the first word line is increased from the first pulse voltage to a fourth pulse voltage.
